(19) United States
(12) Patent Application Publication
(10) Pub. No.: US 2015/0092328 A1
(43) Pub. Date: Apr. 2, 2015

(54) Mobile appliance with an extendable second display

(71) Applicant: Yi-Ting Chen, Kaohsiung (TW)

(72) Inventor: Yi-Ting Chen, Kaohsiung (TW)

(21) Appl. No.: 14/040,748

(22) Filed: Sep. 30, 2013

(51) Int. Cl. G06F 1/16; H05K 5/00

(52) U.S. Cl. CPC G06F 1/1624; H05K 5/0017; H05K 5/0086
USPC 361/679.04

(57) ABSTRACT

An apparatus is provided with a mobile appliance including a front grooved rail member on a bottom and a rear grooved rail member on the bottom, each of the front and rear grooved rail members having a left opening; a second display including front grooved rail on a top and a rear grooved rail on the top, each of the front and rear grooved rails having a right opening; two connection bars each including first and second end enlargements respectively wherein the first enlargements are slidably retained in the front and rear grooved rail members respectively, and the second enlargements are slidably retained in the front and rear grooved rails respectively; two first ICs at one side of the mobile appliance; and two second ICs at an other side of the second display. In an extended position, the first ICs are capable of activating the second ICs.

### BACKGROUND OF THE INVENTION

1. Field of the Invention

The invention relates to mobile appliances and more particularly to a mobile appliance (e.g., mobile phone, tablet computer, etc) having an extendable second display so as to render a larger screen for viewing.

2. Description of Related Art

The use of mobile phones has increased greatly over the last two decades. In fact, mobile phones are now used for a number of purposes beyond simply having a telephone conversation. For example, portable phones are now used to send text messages, to send e-mails, to browse the web, and to play games. A conventional mobile phone (e.g., smart phone) has a multi-touch display. However, its screen is small for some people.

Thus, providing a mobile appliance (e.g., mobile phone, tablet computer, etc) having a large screen is always desirable.

### SUMMARY OF THE INVENTION

It is therefore one object of the invention to provide an apparatus comprising a mobile appliance including a front grooved rail member on a bottom and a rear grooved rail member on the bottom, each of the front and rear grooved rail members having a left opening at one side; a second display including front grooved rail on a top and a rear grooved rail on the top, each of the front and rear grooved rails having a right opening at an other side; two connection bars each including first and second enlargements at both ends respectively wherein the first enlargements of the connection bars are slidably retained in the front grooved rail member and the rear grooved rail member respectively, and the second enlargements of the connection bars are slidably retained in the front grooved rail and the rear grooved rail respectively; two first ICs (integrated circuits) disposed at one side of the mobile appliance; and two second ICs disposed at an other side of the second display; wherein in a retracted position, the second display is disposed directly below the mobile appliance; and wherein in an extended position, the second enlargements contact the right openings of the second display and the first ICs are capable of activating the second ICs to send a video signal from the mobile appliance to the second display.

The above and other objects, features and advantages of the invention will become apparent from the following detailed description taken with the accompanying drawings.

### BRIEF DESCRIPTION OF THE DRAWINGS

FIG. 1 is a top view of an apparatus according to the invention;

FIG. 2A is an exploded view of the apparatus viewing from the right side;

FIG. 2B is a side elevation of the assembled apparatus of FIG. 2A;

FIG. 3A is an exploded view of the apparatus viewing from the left side;

FIG. 3B is a side elevation of the assembled apparatus of FIG. 3A;

FIG. 4 is a sectional view taken along line A-A of FIG. 1;

FIG. 5 is a view similar to FIG. 4 showing the mobile phone moving rightward on the second display for the purpose of enlarging a screen consisting of the display screen of the mobile phone and the second display; and

FIG. 6 is a top view of the apparatus with the second display being fully extended at the end of the movement of FIG. 5.

### DETAILED DESCRIPTION OF THE INVENTION

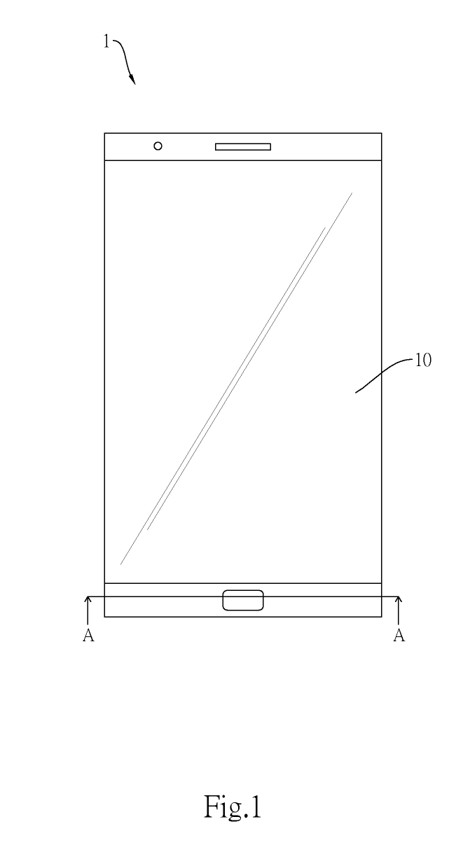

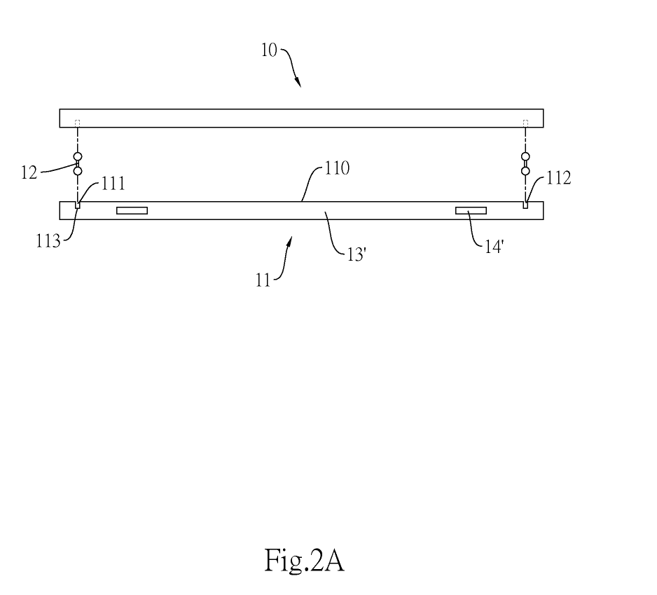

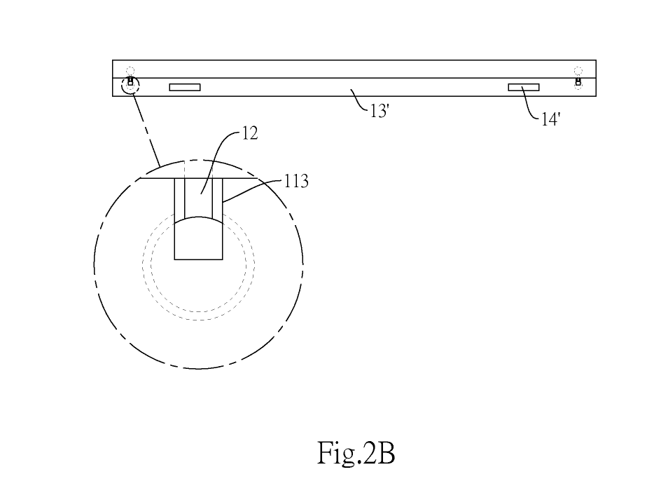

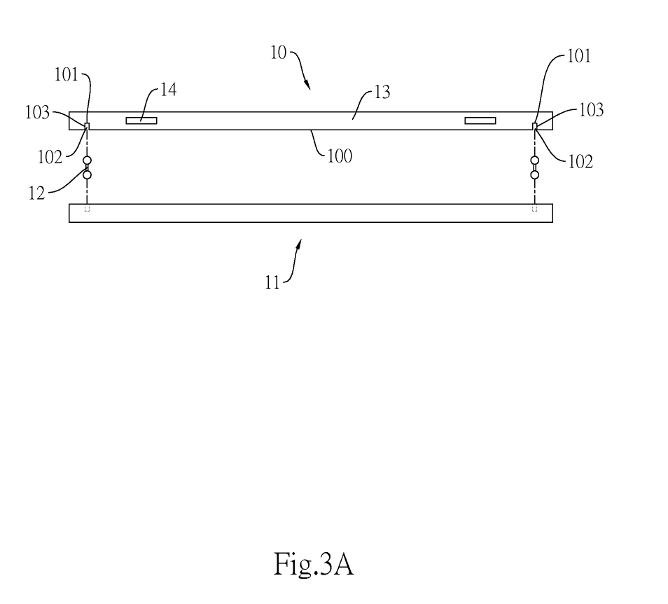

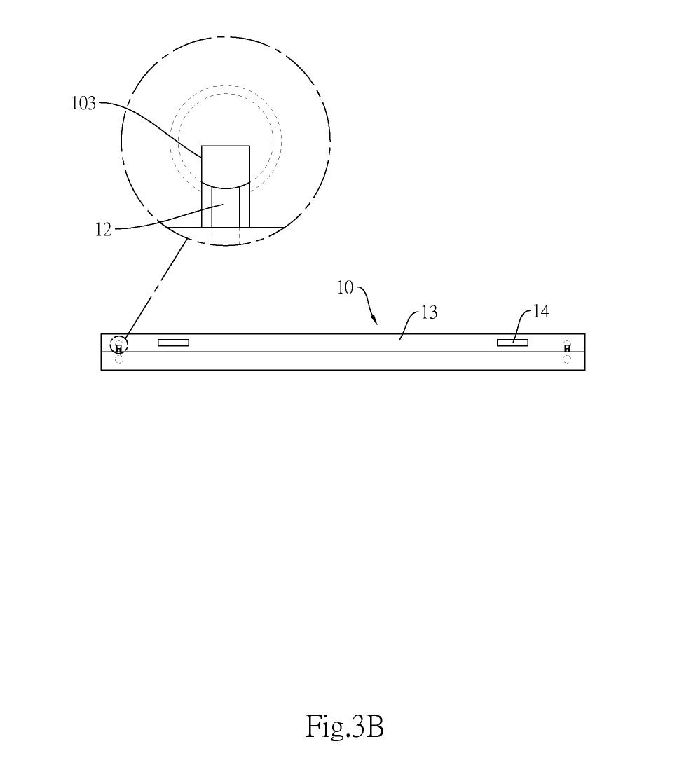

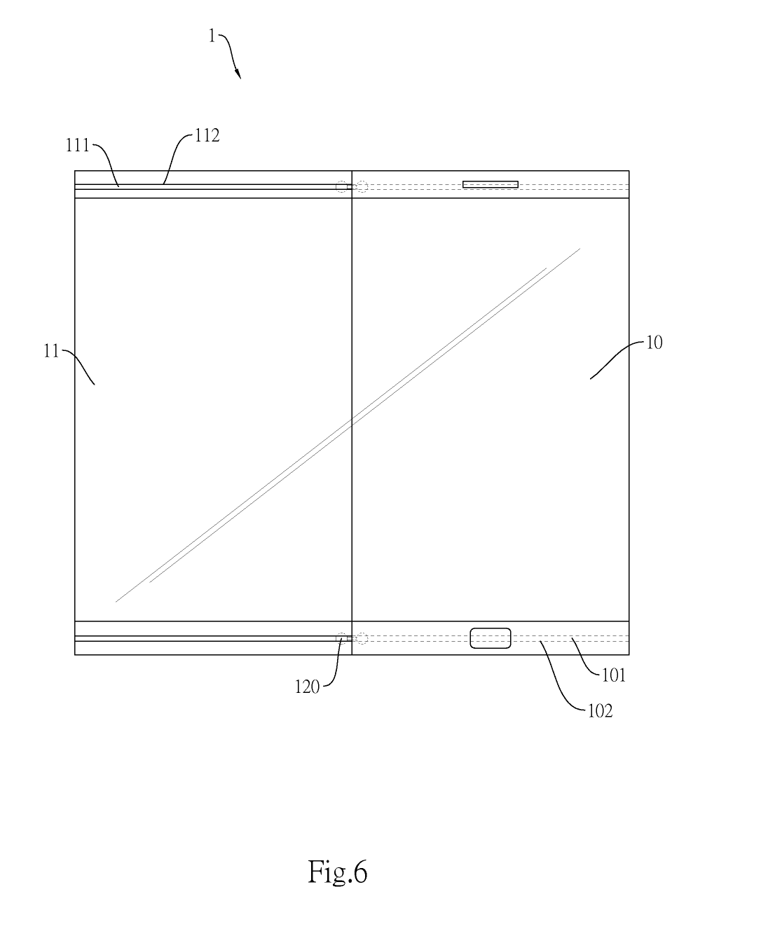

Referring to FIGS. 1 to 6, an apparatus 1 in accordance with the invention comprises the following components as discussed in detail below.

A rectangular mobile appliance (or tablet computer in other embodiment) 10 is disposed on top of a rectangular second display (e.g., multi-touch display) 11. The mobile phone 10 and the second display 11 have the same top (or bottom) area. A bottom 100 of the mobile phone 10 is provided with front and rear grooved rails 101 each having a transverse opening 102 facing downward. The transverse opening 102 has a left opening 103. Likewise, a top 110 of the second display 11 is provided with front and rear grooved rails 111 each having a transverse opening 112 facing upward. The transverse opening 112 has a right opening 113. The front grooved rail 101 corresponds to the front grooved rail 111 and the rear grooved rail 101 corresponds to the rear grooved rail 111 respectively.

Two connection bars 12 each include two enlargements 120 at both ends respectively. One enlargement 120 of the connection bar 12 is disposed in the front (or rear) grooved rail 101 and the other enlargement 120 thereof is disposed in the front (or rear) grooved rail 111 respectively. It is noted that the enlargement 120 is prohibited from disengaging from the opening 112 (113, 102, or 103) because a diameter of the enlargement 120 is greater than the size of the mouth of the opening 112 (113, 102, or 103). One side 13 of the mobile phone 10 is provided with two ICs (integrated circuits) 14 and the other side 13′ of the second display 11 is provided with two ICs 14′ respectively.

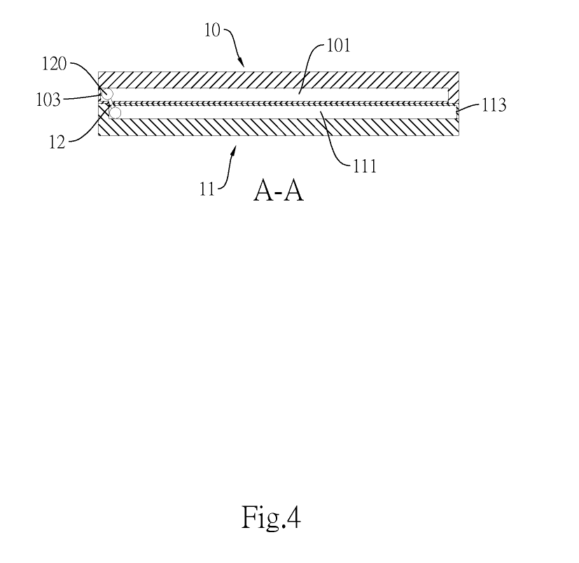

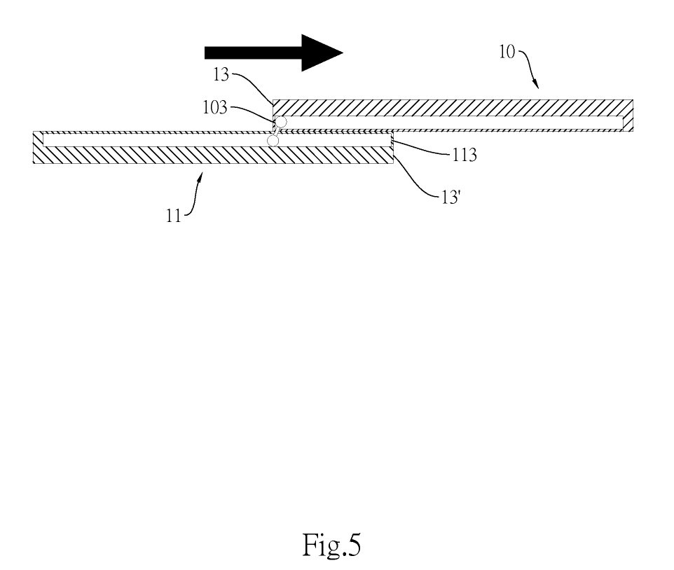

Operation of the invention is discussed in detail below. In a retracted position (see FIGS. 1 and 4), the second display 11 is disposed directly below the mobile phone 10. A user may move the mobile phone 10 rightward by sliding the front connection bar 12 along the front grooved rails 101, 111 and sliding the rear connection bar 12 along the rear grooved rails 101, 111 respectively (see FIG. 5). The movement will be stopped when the lower enlargements 120 contact the right openings 113 of the other side 13′ of the second display 11. At this position, the ICs 14 activate the ICs 14′ to send a video signal from the mobile phone 10 to the second display 11. As a result, images are shown on an enlarged screen consisting of a display of the mobile phone 10 and the second display 11.

While the invention has been described in terms of preferred embodiments, those skilled in the art will recognize that the invention can be practiced with modifications within the spirit and scope of the appended claims.

What is claimed is:

1. An appliance comprising:
a mobile appliance including a front grooved rail member on a bottom and a rear grooved rail member on the bottom, each of the front and rear grooved rail members having a left opening at one side;
a second display including front grooved rail on a top and a rear grooved rail on the top, each of the front and rear grooved rails having a right opening at an other side;
two connection bars each including first and second enlargements at both ends respectively wherein the first enlargements of the connection bars are slidably retained in the front grooved rail member and the rear grooved rail member respectively, and the second enlargements of the connection bars are slidably retained in the front grooved rail and the rear grooved rail respectively;
two first ICs (integrated circuits) disposed at one side of the mobile appliance; and
two second ICs disposed at an other side of the second display;
wherein in a retracted position, the second display is disposed directly below the mobile appliance; and
wherein in an extended position, the second enlargements contact the right openings of the second display and the first ICs are capable of activating the second ICs to send a video signal from the mobile appliance to the second display.

2. The apparatus of claim 1, wherein the mobile appliance is a mobile phone or a tablet computer.

3. The apparatus of claim 1, wherein the second display is a multi-touch display.
